(19) United States
(12) Patent Application Publication
(10) Pub. No.: US 2008/0197369 A1
(43) Pub. Date: Aug. 21, 2008

(54) Double flip semiconductor device and method for fabrication

(75) Inventors: Max Batres, Vashon, WA (US); James Ibbetson, Santa Barbara, CA (US); Nicholas W. Medendorp, Raleigh, NC (US); Julio A. Garceran, Cary, NC (US)

Correspondence Address: KOPPEL, PATRICK & HEYBL, 555 ST. CHARLES DRIVE, SUITE 107, THOUSAND OAKS, CA, 91360, US

(73) Assignee: CREE, INC.

(21) Appl. No.: 11/708,990

(22) Filed: Feb. 20, 2007

(51) Int. Cl. H01L 33/00; H01L 21/00

(52) U.S. Cl. 257/98; 438/29; 257/E33.001; 257/E21.001

(57) ABSTRACT

A double flip-chip semiconductor device formed by a double flip fabrication process. Epitaxial layers are grown on a substrate in the normal fashion with the n-type layers grown first and the p-type layers grown subsequently. The chip is flipped a first time and mounted to a sacrificial layer. The original substrate is removed, exposing the n-type layer, and various additional layers and treatments are added to the device. Because the n-type layer is exposed during fabrication, the layer may be processed in various ways including adding a reflective element, texturing the surface or adding microstructures to the layer to improve light extraction. The chip is flipped a second time and mounted to a support element. The sacrificial layer is then removed and additional layers and treatment are added to the device. The finished device features a configuration in which the layers maintain the same orientation with respect to the support element that they had with the original substrate on which they were grown. Processing the n-type layers, rather than the p-type layers as in a single flip process, provides greater design flexibility when selecting features to add to the device. Thus, previously unavailable processes and reflective elements may be utilized, enhancing the external quantum efficiency of the device.

### BACKGROUND OF THE INVENTION

1. Field of the Invention

This invention relates to semiconductor devices, and more particularly to semiconductor light emitting devices and methods for fabricating same.

2. Description of the Related Art

Light emitting diodes (LED or LEDs) are solid state devices that convert electric energy to light, and generally comprise one or more active layers of semiconductor material sandwiched between oppositely doped layers. When a bias is applied across the doped layers, holes and electrons are injected into the active layer where they recombine to generate light. Light is emitted from the active layer and from all surfaces of the LED.

There has been a great deal of recent interest in LEDs formed of Group-III nitride based material systems because of their unique combination of material characteristics including high breakdown fields, wide bandgaps (3.36 eV for GaN at room temperature), large conduction band offset, and high saturated electron drift velocity. A typical high efficiency LED comprises an LED chip mounted to an LED package and encapsulated by a transparent medium. The efficient extraction of light from LEDs is a major concern in the fabrication of high efficiency LEDs. For conventional LEDs, the external quantum efficiency is limited by total internal reflection (TIR) of light from the LED's emission region. TIR can be caused by the step-down in refractive index between the LED's semiconductor and surrounding ambient, as predicted by Snell's Law. This step-down results in a small escape cone from which light rays from the active region can transmit from the LED chip into the encapsulating medium and ultimately escape from the LED package.

Different approaches have been developed to reduce TIR and improve overall light extraction, with one of the more popular being surface texturing of one or more of the LED chip surfaces. Surface texturing increases the escape probability of the light by providing a varying surface that allows photons multiple opportunities to find an escape cone. Light that does not find an escape cone continues to experience TIR, and reflects off the textured surface at different angles until it finds an escape cone. The benefits of surface texturing have been discussed in several articles. [See Windisch et al., Impact of Texture-Enhanced Transmission on High-Efficiency Surface Textured Light Emitting Diodes, Appl. Phys. Lett., Vol. 79, No. 15, October 2001, Pgs. 2316-2317; Schnitzer et al. 30% External Quantum Efficiency From Surface Textured, Thin Film Light Emitting Diodes, Appl. Phys. Lett., Vol. 64, No. 16, October 1993, Pgs. 2174-2176; Windisch et al. Light Extraction Mechanisms in High-Efficiency Surface Textured Light Emitting Diodes, IEEE Journal on Selected Topics in Quantum Electronics, Vol. 8, No. 2, March/April 2002, Pgs. 248-255; Streubel et al. High Brightness AlGaNInP Light Emitting Diodes, IEEE Journal on Selected Topics in Quantum Electronics, Vol. 8, No. March/April 2002].

U.S. Pat. No. 6,657,236, also assigned to Cree Inc., discloses structures for enhancing light extraction in LEDs through the use of internal and external optical elements formed in an array. The optical elements have many different shapes, such as hemispheres and pyramids, and may be located on the surface of, or within, various layers of the LED. The elements provide surfaces from which light refracts or scatters.

Another method used to fabricate more efficient semiconductor devices is called flip-chip mounting. Flip-chip mounting of LEDs involves mounting the LED onto a submount substrate-side up. Light is then extracted and emitted through the transparent substrate. Flip-chip mounting is an especially desirable technique for mounting SiC-based LEDs. Since SiC has a higher index of refraction than GaN, light generated in the active region does not internally reflect (i.e. reflect back into the GaN-based layers) at the GaN/SiC interface. Flip-chip mounting of SiC-based LEDs offers improved light extraction when employing certain chip-shaping techniques known in the art. Flip-chip packaging of SiC LEDs has other benefits as well, such as improved heat extraction/dissipation, which may be desirable depending on the particular application for the chip.

A mirror material may be used to coat one or more of the layers of the device to enhance light extraction by reflecting light emitted from the active layers away from the substrate or other photon absorbing materials. In the case of III-nitride LEDs, the LED usually comprises a p-type cap layer due to the difficulties associated with depositing high quality layers over p-type layers. In the flip-chip configuration, mirror materials are therefore limited to those materials that make good ohmic contacts to p-type layers. It would be preferable to form the mirror on n-type layers instead; however, reversing the growth order of the layers is not practical in nitride LEDs because p-type layers must be grown on top of n-type layers to minimize defects in the active region.

Referring to FIG.1, a semiconductor device 100 having the flip-chip configuration is shown. The flip-chip structure is known and only briefly described below. Active layer 102 is interposed between n-type layers 104 and p-type layers 106. A mirror 108 is shown contacting p-type layers 106 opposite the active layer 102. The mirror 108 is also bonded to a carrier wafer 110 with a metal bond 112. Carrier electrode 114 provides an electrical contact to the carrier wafer. Voltage is applied across the device 100 with carrier electrode 114 and wire bond pad 116, and light is emitted by radiative recombination in the active layer 102. Mirror 108 reflects light emitted from the active layer 102 away from the light absorbent carrier wafer 110 toward a textured surface 118. The n-type layers 104 are processed to achieve the textured effect. The textured surface 118 helps to prevent total internal reflection and increases the efficiency of the device.

P-type layers 106 are shown interposed between the carrier wafer and the n-type layers 104. This arrangement is due to the flip-chip fabrication process. It is known in the art that p-type layers should be grown on top of n-type layers, thus it is evident to one of ordinary skill in the art that the chip has been flipped and bonded to a carrier wafer after the epitaxial layers were grown. The original epitaxial growth substrate (not shown) can be removed by any of several well known processes, such as etching, grinding or ablation.

### SUMMARY OF THE INVENTION

The present invention as embodied in the claims discloses new semiconductor devices, such as LED chips and vertical-cavity surface-emitting lasers, that have enhanced light extraction efficiency and methods for fabricating the new devices. One embodiment of a semiconductor device according to the present invention comprises a carrier wafer having first and second surfaces. An active region is disposed between a layer of p-type semiconductor material and a layer of n-type semiconductor material. A p-contact electrode is disposed on the p-type material opposite the active region. A reflective element is disposed on the layer of n-type material opposite the active region. The reflective element is mounted to first surface of the carrier wafer, such that the reflective element is interposed between the layer of n-type material and the carrier wafer. A carrier electrode is disposed on the second surface of the carrier wafer opposite the reflective element.

Another embodiment of a semiconductor device according to the present invention comprises a light emission region having an active layer interposed between a layer of p-type semiconductor material and a layer of n-type semiconductor material. A reflective element is disposed on the layer of n-type material opposite the active layer. A p-contact electrode is disposed on the layer of p-type material opposite the active layer. A conductive metal layer is disposed on the reflective element opposite the layer of n-type material. The conductive metal layer should be thick enough to provide mechanical structure of the semiconductor device.

Another embodiment of a semiconductor device according to the present invention comprises an active region interposed between a layer of p-type semiconductor material and a layer of n-type semiconductor material. A reflective element is disposed on a surface of the layer of n-type material opposite from the active region. A support element is disposed on the reflective element opposite the layer of n-type material, such that the reflective element is interposed between the layer of n-type material and the support element. The support element is structured to provide mechanical support to the semiconductor device.

Another embodiment of a semiconductor device according to the present invention comprises a support element and an active region interposed between a layer of p-type material and a processed layer of n-type material. The processed layer of n-type semiconductor material is mounted on the support element.

One embodiment of a method for fabricating semiconductor devices according to the present invention comprises providing a substrate suitable for growing epitaxial semiconductor layers. At least one n-type semiconductor layer is grown on the substrate. Next, an active region is grown on the n-type layer. Then, at least one p-type semiconductor layer is grown on the active region. A p-contact electrode is formed on said p-type layer. Then, the semiconductor device is flipped a first time and mounted to a sacrificial carrier (e.g., a polymer material, wafer, etc.) such that the n- and p-type layers are interposed between the substrate and the sacrificial carrier. The substrate is then removed and a portion of the n-type layer is exposed. A reflective element is formed on the exposed n-type layer. The semiconductor device is flipped a second time and the reflective element is mounted to a support element. The sacrificial carrier is removed.

One embodiment of a double flip-chip semiconductor device according to the present invention comprises a support element. A first semiconductor layer which was grown on a growth substrate has been removed from the growth substrate and is disposed on the support element. A second semiconductor layer is grown on the first semiconductor layer. An active layer is interposed between the first and second semiconductor layers.

These and other aspects and advantages of the invention will become apparent from the following detailed description and the accompanying drawings which illustrate by way of example the features of the invention.

### BRIEF DESCRIPTION OF THE DRAWINGS

FIG. 1 is a cross-sectional view of a semiconductor device according to a known embodiment disclosed in the prior art.

FIGS. 2a-g are cross sectional views of one embodiment of a semiconductor device according to the present invention shown at various stages of the fabrication process.

FIG. 3 is a cross-sectional view of another embodiment of a semiconductor device according to the present invention.

FIG. 4 is a cross-sectional view of another embodiment of a semiconductor device according to the present invention.

FIG. 5 is a cross-sectional view of another embodiment of a semiconductor device according to the present invention.

FIG. 6 is a cross-sectional view of another embodiment of a semiconductor device according to the present invention.

FIG. 7a is a cross-sectional view of another embodiment of a semiconductor device according to the present invention.

FIG. 7b is a plan view of another embodiment of a semiconductor device according to the present invention.

FIG. 8 is a cross-sectional view of another embodiment of a semiconductor device according to the present invention.

FIG. 9 is a cross-sectional view of another embodiment of a semiconductor device according to the present invention.

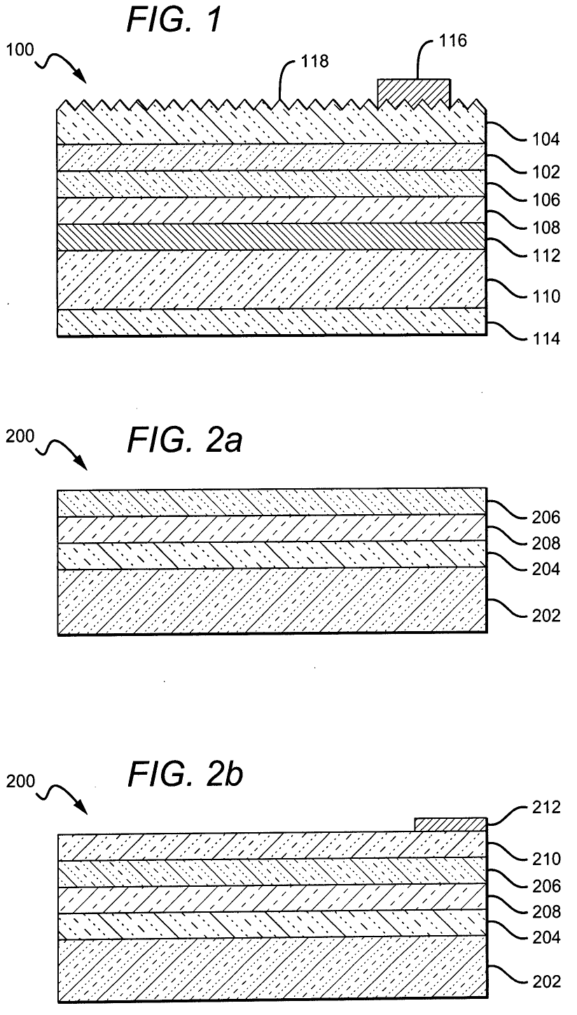

### DETAILED DESCRIPTION OF THE INVENTION

The present invention enables improved performance for semiconductor devices, such as LEDs for example, by providing enhanced light extraction efficiency. The present invention also provides methods for fabricating these devices. Similarly as in other semiconductor devices, a bias voltage is applied across the device and light is emitted as a result of radiative recombination in the active region of the device. Various elements and procedures can be used to increase the light output of the device. For example, layers of reflective materials functioning as mirrors can be formed at certain locations within the device to reflect emitted light away from photon absorbing materials such as the substrate. Another method often employed in the art is to roughen or texture one or more of the layers to prevent total internal reflection.

The present invention provides a novel double flip fabrication process, yielding a structure that allows the designer to incorporate features similar to those mentioned above to achieve a more efficient semiconductor device. The double flip-chip structure allows the n-type layer to be processed before the device is completed. This is possible because the n-type layer can be exposed and accessed prior to the second flip and mount steps during fabrication. The accessible n-type layer can be processed in several different ways. For example, when the n-type layer is exposed, it may have various materials deposited on it or it may have a surface modified. Light extraction elements and structures, such as those disclosed in U.S. Pat. No. 6,657,236 to Cree, Inc., might also be formed. The exposed n-type layer may also be processed by texturing or roughening the surface of the layer by etching, grinding or ablation. The double flip-chip structure provides that these and other features may be added to the n-type layer to yield a processed n-type layer that improves the light extraction of the device.

As mentioned above, the double flip-chip structure allows materials to be disposed on the n-type semiconductor layers rather than the p-type layers. This is beneficial because n-type layers can accommodate many different materials, whereas p-type layers present more constraints. As discussed in detail below, the double-flip fabrication process affords the designer greater flexibility, enabling the designer to use previously unavailable materials and techniques in the fabrication of the device without changing the order in which the epitaxial layers are grown.

Although discussed in detail below, the double flip-chip structure is not limited to those embodiments in which an n-type layer is grown first and then later exposed for processing after the device is mounted to a carrier element. Other layer growth orders are possible. For example, in some cases it may be desirable to grow a p-type layer or another type of layer first and then expose that layer for processing. Depending on the embodiment, the processing to the exposed first-grown semiconductor layer can include any post growth steps, such as surface preparation, addition of layer(s) (including reflector, bonding and/or barrier layers), patterning, etching, texturing, implantation, and other processing treatments.

It is understood that when an element such as a layer, region or substrate is referred to as being “on” another element, it can be directly on the other element or intervening elements may also be present. Furthermore, relative terms such as “inner”, “outer”, “upper”, “above”, “lower”, “beneath”, and “below”, and similar terms, may be used herein to describe a relationship of one layer or another region. It is understood that these terms are intended to encompass different orientations of the device in addition to the orientation depicted in the figures.

Although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

It is noted that the terms “layer” and “layers” are used interchangeably throughout the application. A person of ordinary skill in the art will understand that a single “layer” of semiconductor material may actually comprise several individual layers of material. Likewise, several “layers” of material may be considered functionally as a single layer. In other words the term “layer” does not denote an homogenous layer of semiconductor material. A single “layer” may contain various dopant concentrations and alloy compositions that are localized in sub-layers. Such sub-layers may function as buffer layers, contact layers or etch-stop layers, for example. These sub-layers may be formed in a single formation step or in multiple steps. Unless specifically stated otherwise, the Applicant does not intend to limit the scope of the invention as embodied in the claims by describing an element as comprising a “layer” or “layers” of material.

Embodiments of the invention are described herein with reference to cross-sectional view illustrations that are schematic illustrations of idealized embodiments of the invention. As such, variations from the shapes of the illustrations as a result, for example, of manufacturing techniques and/or tolerances are expected. Embodiments of the invention should not be construed as limited to the particular shapes of the regions illustrated herein but are to include deviations in shapes that result, for example, from manufacturing. A region illustrated or described as square or rectangular will typically have rounded or curved features due to normal manufacturing tolerances. Thus, the regions illustrated in the figures are schematic in nature and their shapes are not intended to illustrate the precise shape of a region of a device and are not intended to limit the scope of the invention.

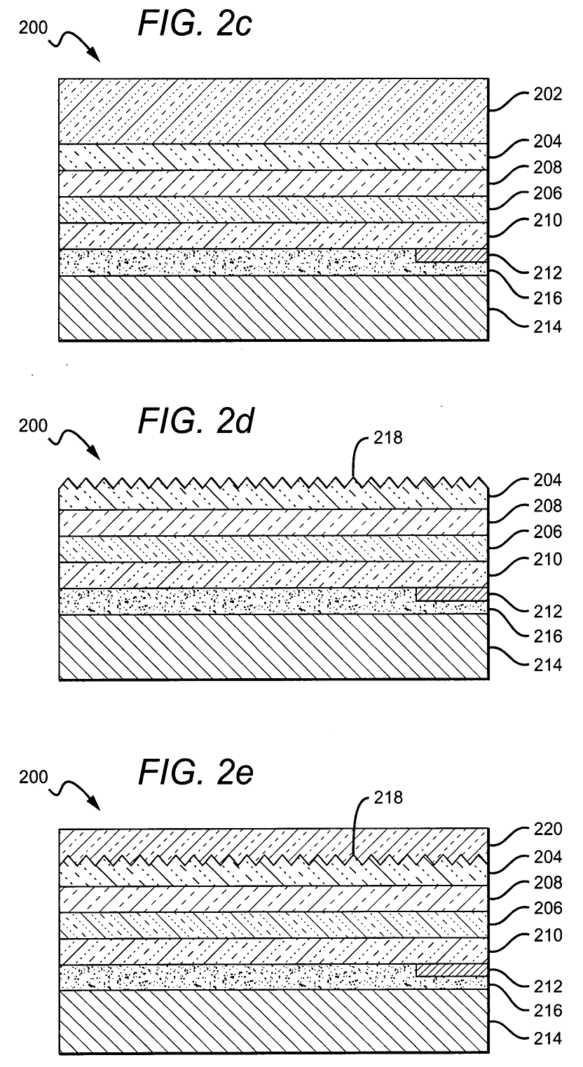

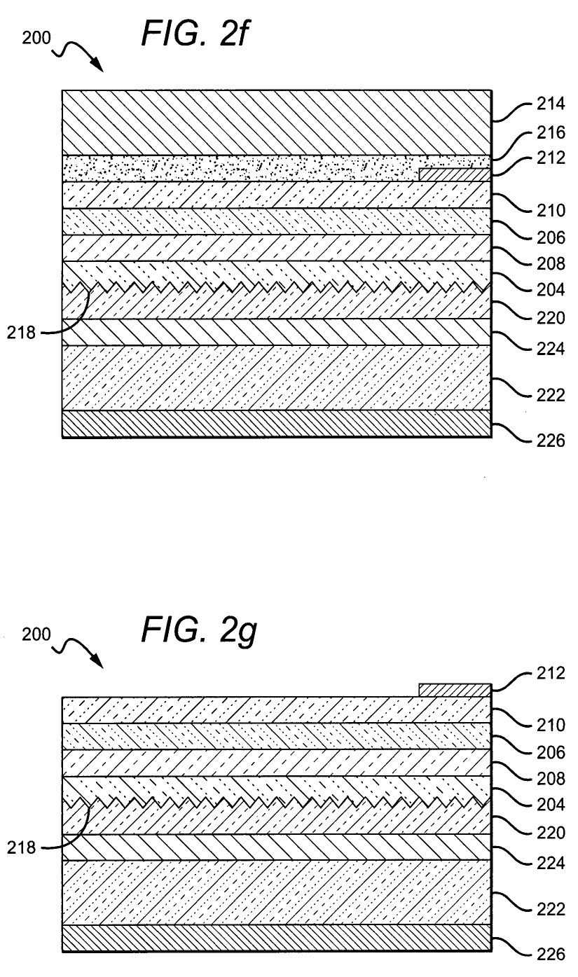

Referring now to FIGS. 2a-g, one embodiment of a semiconductor device 200 according to the present invention is shown in various steps of fabrication. For ease of description and understanding, the device 200 is shown as an individual device during a fabrication process. It is understood, however, that semiconductor devices are typically fabricated at the wafer level with the individual devices singulated from the wafer in a subsequent processing step. However, the process described herein can also be used for fabricating individual devices. It is also understood that although the fabrication steps are shown in a particular order below, the device 200 can be fabricated by steps in a different order and can include additional or fewer steps.

Furthermore, additional features may be added to the devices at the wafer level or individually after the devices have been singulated. For example, it is known in the art that adding an encapsulant with a large index of refraction can improve the light extraction. Typical encapsulant materials have an index of refraction (n) of approximately 1.5 while materials such as GaN and SiC have indices of refraction in excess of 2. It is often desirable to match the indices of refraction of the encapsulant material and the semiconductor material to avoid an index step. For this reason, large index of refraction materials (n>1.5) may be used to increase efficiency. Additionally, encapsulants may include materials such as wavelength-converting phosphors enabling the devices to emit light of a certain color. These and several other known features may be added to the invention as disclosed below in order to achieve specific design goals. It is understood that although some of these features are not explicitly discussed below in detail, a person of skill in the art would know to add them during fabrication or at a point after the devices have been fabricated either before or after singulation.

FIG. 2a shows epitaxial layers grown on a substrate 202. The oppositely doped n-type and p-type layers 204, 206 and active region 208 interposed between them are typically formed on a substrate 202 using known fabrication methods and devices, such as epitaxial growth in a metalorganic chemical vapor deposition (MOCVD) reactor. The semiconductor layers 202, 204, 206 can be from the Group-III nitride system. Group-III nitrides refer to those semiconductor compounds formed between nitrogen and the elements in the Group III of the periodic table, usually aluminum (Al), gallium (Ga), and indium (In). The term also refers to ternary and quaternary compounds such as aluminum gallium nitride (AlGaN) and aluminum indium gallium nitride (AlInGaN). In a preferred embodiment, the n- and p-type layers 204, 206 are gallium nitride (GaN) and the active region 208 is a multiquantum well (MQW) having alternating layers of GaN and InGaN. In alternative embodiments the n- and p-type layers 204, 206 can be or may include Group III-V materials or alloys thereof, such as AlGaN, AlInGaN, aluminum gallium arsenide (AlGaAs) or aluminum gallium indium arsenide phosphide (AlGaInAsP).

The substrate 202 can be made of many materials such as sapphire, silicon carbide, aluminum nitride (AlN), GaN, with a suitable substrate being a 4H polytype of silicon carbide, although other silicon carbide polytypes can also be used including 3C, 6H and 15R polytypes. Silicon carbide (SiC) has certain advantages, such as a closer crystal lattice match to Group III nitrides than sapphire and results in Group III nitride films of higher quality. Silicon carbide also has a very high thermal conductivity so that the total output power of Group-III nitride devices on silicon carbide is not limited by the thermal dissipation of the substrate (as may be the case with some devices formed on sapphire). SiC substrates are available from Cree Research, Inc., of Durham, N.C. and methods for producing them are set forth in the scientific literature as well as in U.S. Pat. Nos. Re. 34,861; 4,946,547; and 5,200,022.

Although it is possible to grow either n-type or p-type layers first on a growth substrate, it may be preferable to grow the n-type layers first. This is the case for several reasons that are known in the art. One reason for growing the n-type layers first is that they are grown at higher temperatures than the p-type layers; n-type layers are grown at temperatures around 1100° C., and p-type layers are grown around 900° C. When p-type layers are subjected to temperatures in excess of 900° C., the dopant material (often magnesium) can diffuse into adjacent layers, reducing the quality of the layer. Thus, once the n-type layers have been grown on the substrate, subsequent p-type layers can be grown at lower temperatures that do not substantially affect the n-type layers that have already been formed. Another reason for growing n-type layers first is that layers grown on the substrate must be grown for longer periods of time to overcome the lattice mismatch at the substrate interface. Layers grown longer are grown thicker. Because p-type layers are more light-absorbent than n-type layers, it is desirable to have a thicker n-type layer so that less emitted light is absorbed.

In FIG. 2a n-type layer 204 is shown grown first on substrate 202. Then, p-type layer 206 is grown on n-type layer 204 and the active region 208 is formed in between. The active region 208 can comprise single quantum well (SQW), multiple quantum well (MQW), double heterostructure or super lattice structures. It is understood that additional layers and elements can also be included in the device 200, including but not limited to buffer, nucleation, contact and current spreading layers and superlattice structures on one or both sides of the active region 208 as well as light extraction layers and elements.

FIG. 2b shows p-contact electrode 210 formed on p-type layer 206. P-contact electrode 210 can comprise several conductive materials, such as transparent conductive oxides or thin metals, for example, zinc oxide (ZnO), indium tin oxide (InSnO or ITO), and ultra-thin platinum (Pt). P-contact electrode 210 helps to distribute current evenly across the p-type layer 106. The p-contact electrode 210 should be made of a material and have a thickness such that the light emitted from the active region 208 can pass through the p-contact electrode 210 with minimal loss. In one configuration, the p-contact electrode 210 functions as a current spreading layer that is deposited on what will become the primary emitting surface of p-type layer 206. The p-contact electrode 210 may comprise a metal, such as Pd, Ni or Au, having a thickness of between approximately 2 nm and 20 nm; a transparent conducting oxide, such as indium tin oxide, having a thickness of approximately 100 nm; a semiconductor material; or a combination of these materials. Other materials and thicknesses may also be used.

A wire bond pad 212 is disposed on a portion of the p-contact electrode 210. The wire bond pad 212 provides an electrical connection from an off-chip voltage/current source (not shown) to the device 200.

FIG. 2c shows device 200 inverted with respect to FIGS. 2a, b. The device has been flipped a first time and bonded to a sacrificial carrier 214 with a temporary removable adhesive 216. Sacrificial carrier 214 provides mechanical support to the semiconductor layers 204, 206, 208 while the unfinished device 200 is being processed. Temporary adhesive 216 covers substantially all of the surface of p-contact electrode 210 and substantially all of the surface of wire bond pad 212 as shown in FIG. 2c.

In FIG. 2d substrate 202 has been removed, exposing the n-type layer 204. Substrate 202 can be removed by several known methods including wet and dry etching processes or laser ablation. Once the n-type layer 204 is exposed, it may be processed in several different ways.

As mentioned above, it may be desirable to modify (e.g., texture or roughen) various surfaces on or within the device to provide a multitude of angled surfaces and increase light extraction. A modified surface improves light extraction by providing a varying surface that allows light that would otherwise be trapped in the LED, by total internal reflection (TIR), to escape as emitted light. The variations in the modified surface increase the chances that the light will reach an emission surface within the critical angle (as defined by Snell's law) and will be emitted. For light that does not escape through the modified surface, the variations of the modified surface reflect the light at different angles, increasing the chances that the light will escape on the next pass. Additional embodiments of LEDs having a modified surface are described below.

One embodiment of a device 200 with a modified surface 218 is shown in FIG. 2d. There are several known methods by which a semiconductor surface may be modified. The surface may have portions removed by processes such as etching, grinding or ablation. It is also possible to add material, such as nanoparticles or light extraction elements for example, to the surface in order to give it a non-uniform texture. Adding light extraction structures to a surface within the device is discussed at length in U.S. Pat. No. 6,657,236 assigned to Cree, Inc. Another surface modification method is to damage the surface by subjecting it to high temperatures or polishing it. A combination of any of these processes may also achieve the desired surface modifications.

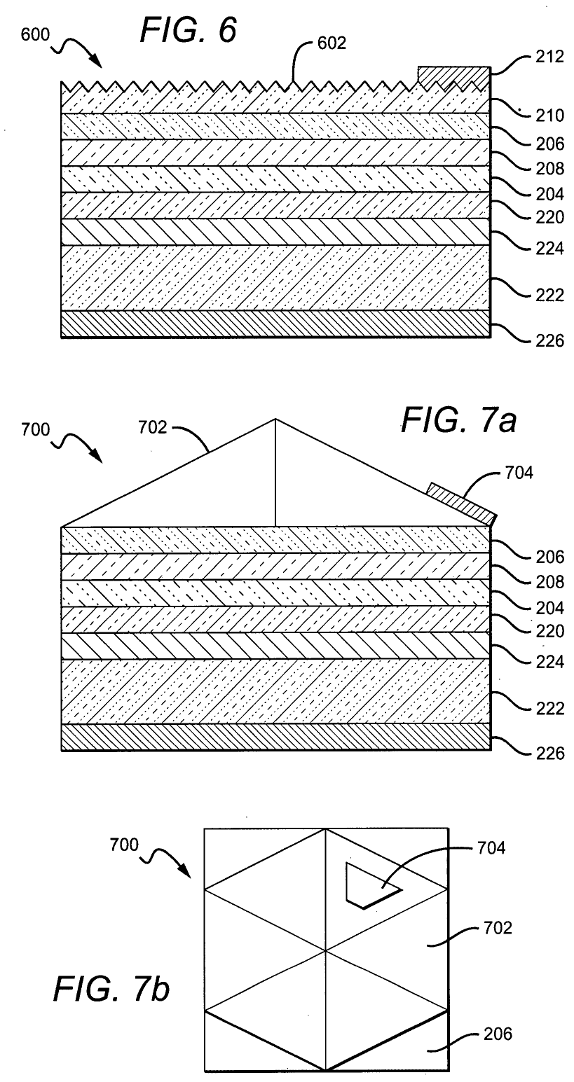

Although the modified surface 218 is shown as a surface of the n-type layer 204 opposite the active region 208 in FIG. 2d, it is understood that many different surfaces within the device 200 may be modified to achieve the same extraction enhancing effect. Device 200 may also have no modified surfaces at all. Some alternate embodiments with various modified surfaces are discussed below, referring to FIGS. 5 and 6.

The n-type layer may also be processed by disposing materials on one or more of its surfaces. FIG. 2e shows a semiconductor device 200 with a reflective element 220 disposed on the modified surface 218 of n-type layer 204. As will be understood by the discussion below, if a light emitting diode (LED) is being fabricated, this reflective element 220 helps increase the useful light extraction of the device 200. Reflective element 220 can comprise a mirror, a distributed Bragg reflector (DBR), and other types of reflectors. Reflective element 220 is shown formed on n-type layer 204. Due to the growth process of the semiconductor layers, n-type layer 204 is thicker and more laterally conductive than p-type layer 206 and is therefore capable of supporting more lateral current flow. Since current can easily spread laterally within the n-type layer 204, it is not necessary that the reflective element 220 make an excellent uniform ohmic contact at all points on the surface of the n-type layer as would be necessary if the reflective element 220 was disposed on the p-type layer 206 as in a single flip-chip process. Because the reflective element 220 is not limited to those materials and configurations that form a uniform ohmic contact with the n-type layer 204, many different types of reflective elements can be used. This allows for the use of highly reflective materials in the double flip-chip process, leading to improved external quantum efficiency.

Reflective element 220 may comprise metal mirrors made of materials including aluminum, silver, gold, rhodium, platinum, palladium, gold tin or combinations thereof, which can be deposited on the surface of n-type layer 204 using conventional methods, such as sputtering. A preferred material for a mirror comprises aluminum due to its high reflectivity (especially at shorter wavelengths) which can be in excess of 90%. Furthermore, aluminum makes a good ohmic contact with n-type layers and because aluminum can withstand temperatures in excess of 350° C., the process window for fabrication and packaging is widened. An alternative embodiment wherein the reflective element 220 comprises a distributed Bragg reflector (DBR) is discussed in more detail below referring to FIG. 4.

In FIG. 2f device 200 is shown inverted with respect to FIG. 2e. The device 200 has been flipped a second time, resuming the orientation that it originally had when the epitaxial semiconductor layers 204, 206, 208 were grown as shown in FIG. 2a. Reflective element 220 is mounted to a carrier wafer 222. Carrier wafer 222 may comprise various semiconductor materials with a preferred material being silicon. The original growth substrate may also be recycled to function as the carrier wafer. In other embodiments discussed below, the carrier wafer may be replaced by other types of support elements including various layers of metals, such as aluminum or copper, or other materials such as glass. The reflective element 220 is joined to the carrier wafer 222 with bonding layer 224. The bonding layer 224 may comprise a eutectic metal bond using, for example, gold tin (AuSn). Alternatively, it may comprise other conductive materials such as nickel tin (NiSn) or conductive epoxy. Other bonding and/or barrier layers of different materials may be used.

Carrier wafer 222 should provide a good electrical connection to n-type layer 204 while at the same time providing mechanical support to the rest of the device 200. A carrier electrode 226 may be disposed on the carrier wafer 222 to facilitate connection to an outside voltage/current source. The carrier electrode 226 may comprise several highly conductive materials such as gold, silver, platinum, and various alloys. Carrier electrode 226 may function as a current spreading layer to help evenly distribute the current over the surface of the carrier wafer 222. Contact elements (not shown) may also be disposed on the carrier electrode 226.

Once the carrier wafer 222 has been bonded to the n-type layer 204, the device has proper mechanical support and the sacrificial carrier 214 and the removable adhesive 216 can be removed as shown in FIG. 2g. The device 200 can be biased with now exposed wire bonding pad 212 and carrier electrode 226. As noted above, the double flip-chip process yields a chip where the epitaxial layers retain the same orientation that they had immediately after the growth stage. Compare the growth stage with the finished chip in which the n-type layer 204 rather than the p-type layer 206 is proximate to the substrate 202 (see FIG. 2a) and the carrier wafer 222 (see FIG. 2g), respectively. In alternative embodiments, the bonding pad 212 can be put on after the sacrificial carrier 214 is removed from the p-contact electrode 210.

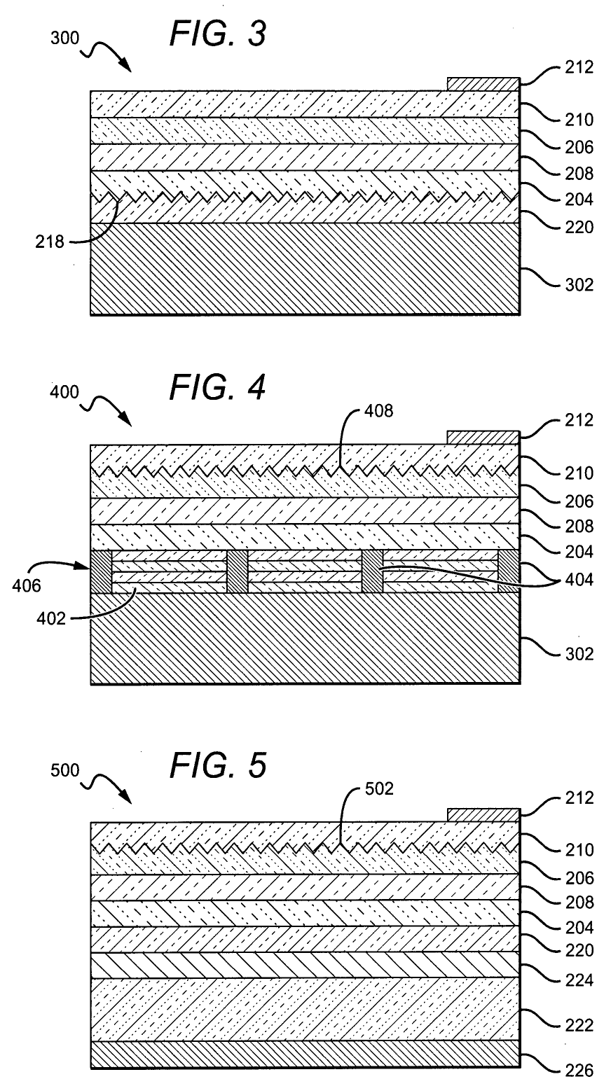

FIG. 3 illustrates another embodiment of a semiconductor device 300 according to the present invention. Device 300 is similar to device 200 and contains several of the same elements. In device 300, reflective element 220 is disposed on conductive metal layer 302 rather than on a carrier wafer.

The thick conductive metal layer 302 may be applied to the reflective element 220 by electroplating, for example. The conductive metal layer 302 should be thick enough to provide mechanical support to the finished device. A layer should be at least 50 μm thick, with a preferred thickness in the range of 300-400 μm. Although several different metals and metal alloys can be used, copper (Cu) is a preferred material.

Because the device 300 does not need to be bonded to a separate carrier wafer, expensive bonding steps are no longer necessary in the fabrication process, reducing the overall cost of the finished device. Furthermore, the reliability of the device 300 may be improved by eliminating the possibility of voids at the bonding interface between the reflective element 220 and the carrier wafer 214.

Another embodiment of a semiconductor device 400 according to the present invention is shown in FIG. 4. The device 400 functions similarly as device 200 and shares many common elements. The reflective element in this embodiment comprises an omnidirectional reflector (ODR) 402.

The ODR 402 may be a distributed Bragg reflector (DBR) which generally comprises multiple pairs (typically 5-50 pairs) of two materials having different refractive indexes. As a result of the difference in the refractive index, Fresnel reflection occurs at each of the interfaces. The reflection at each interface may not be total, but because of the number of interfaces and the thicknesses of the different layers, the reflected waves constructively interfere so that the DBR provides good reflectivity. The thicknesses of the layers are chosen to ensure that substantially all of the reflected waves constructively interfere with each other [See J. Lin, Design and fabrication of Omnidirectional Reflectors in the Visible Range, Journal of Modern Optics, Vol. 52, No. 8, May 2005, Pgs. 1155-1160.] Depending on the type of material used for the DBR, it can be deposited on the surface of n-type layer 204 with the same method used to fabricate the epitaxial layer(s), such as MBE or MOCVD. These layers may also be deposited by methods including electron beam deposition, sputter deposition, etc. By choosing the appropriate materials and tailoring the layer design, it is possible to create a reflective element with reflectivity much greater than 90% over all angles of incidence and a range of wavelengths, significantly reducing the optical absorption of the device 400.

Another advantage is that the materials used to construct the ODR do not themselves have to be conductive. Instead, a composite mirror 406 with very high average reflectivity can be achieved by incorporating an ODR 402 with small regions of conventional ohmic electrodes 404 connected by a conductive backing layer (not shown) interposed between the ODR 402 and the conductive metal layer 302 using, for example, aluminum. Although ODR 402 is shown having only two pairs of layers in FIG. 4, it is understood that the figure is only representative of the ODR 402 which typically comprises up to 50 pairs of layers as mentioned above. Even more pairs can be used if needed. Because device 400 utilizes an ODR 402, the surface of n-type layer 204 that interfaces with ODR 402 is preferably not roughened. Modified surface 408 is shown as one surface of the p-type layer 206. However, other surfaces within the device such as the p-contact electrode may be modified as noted above, or the device 400 may have surfaces that are modified.

A semiconductor device fabricated with the double flip-chip process is particularly well-suited to the implementation of a composite mirror since the ability of the n-type layers to conduct current laterally allows the average reflectivity of the mirror to be maximized without affecting the active device area.

Referring to FIGS. 5 and 6, additional embodiments of semiconductor devices according to the present invention are shown. Devices 500, 600 are similar to device 200 and share several common elements. The device 500 comprises p-type layer 206 with a modified surface 502. Modified surface 502 functions to enhance light extraction similarly as modified surface 218 shown in FIGS. 2d-g and may be formed by several methods known in the art including those discussed above regarding surface 218.

Device 600 comprises p-contact electrode 210 having modified surface 602. Again, the modified surface 602 serves to enhance light extraction and can be formed by many known methods including those discussed above regarding surface 218.

FIGS. 7a, 7b depict another embodiment of a semiconductor device 700 according to the present invention. The device 700 has a modified surface 702 with wire bond pad 704 disposed thereon. In FIG. 7b, p-type layer 206 is shown protruding from beneath modified surface 702. Wire bond pad 704 is disposed on modified surface 702, providing an electrical connection to a voltage/current source (not shown). U.S. Pat. No. 6,657,236, also assigned to Cree Inc., discloses structures for enhancing light extraction in LEDs through the use of internal and external optical elements formed in an array. The optical elements have many different shapes, such as hemispheres and pyramids, and may be located on the surface of, or within, various layers of the LED. The elements provide surfaces from which light refracts or scatters.

Although modified surface 702 is shown as a pyramid with a hexagonal base, many different shapes can be used for various embodiments of the device to provide the best light extraction. FIG. 7a shows a cross-sectional view of one example of a shape that can be used. FIG. 7b shows a plan view of the device 700. The shape can be chosen and adjusted to give the best light extraction for a given embodiment. The different shapes are formed by using different combinations of semiconductor materials and/or mask layers with standard wet chemical, dry etching, laser or wafer sawing techniques. The shape shown in the figure represents only one of many possible shapes and the scope of this invention should not be limited to the shape shown.

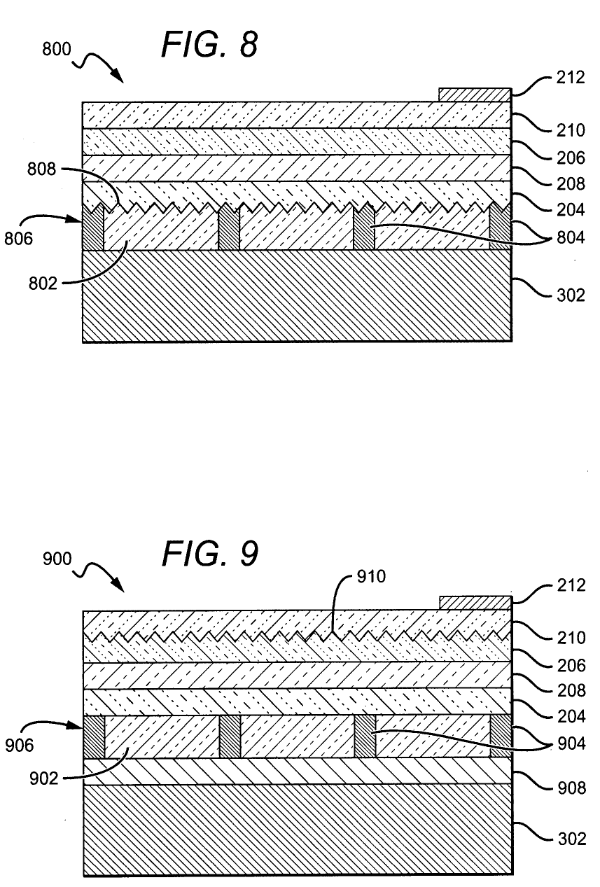

FIGS. 8 and 9 illustrate two more embodiments of a semiconductor device 800, 900 according to the present invention. Devices 800, 900 are similar to device 200 and share several common elements.

In device 800, composite mirror 806 is shown disposed on conductive metal layer 302. Composite mirror 806 comprises ohmic electrodes 804 and a refractive material 802. Refractive material 802 should have an index of refraction that is lower than the materials adjacent to it. Some materials that may be used for the low index refractive material are SiO₂, SiN or air, for example. Ohmic electrodes 804 provide an electrical connection between the n-type layer 204 and the conductive metal layer 302. Because it is not necessary to make a uniform ohmic contact across the entire composite mirror 806 with the n-type layer 204, a high average reflectivity can be achieved. Modified surface 808 is shown as a surface of n-type layer 204 at the interface of n-type layer 204 and the composite mirror 806. Other surfaces in the device 800 can also be modified as discussed above to improve light extraction, or the device 800 may contain no modified surfaces.

Additionally, the refractive material 802 may comprise a metamaterial having a negative index of refraction. Metamaterials are typically synthetic materials having properties that depend chiefly on their structure rather than their composition. Some metamaterials that have been created exhibit a negative index of refraction. Such materials are known in the art. [See generally: “SPECIAL ISSUE ON NANOSTRUCTURED OPTICAL META-MATERIALS: BEYOND PHOTONIC BANDGAP EFFECTS”, J. Opt. A: Pure Appl. Opt., Vol. 7, No. 2, February 2005.] The metamaterials have similar dimensions as photonic crystals and may be applied with similar processing methods such as nanoimprinting, holography or e-beam lithography. Other methods of application may also be used. The metamaterial can be interposed between the n-type layer 204 and the conductive metal layer 302 as shown in FIG. 8 with ohmic electrodes 804 providing an electrical connection between the n-type layer 204 and the conductive metal layer 302.

Device 900 includes composite mirror 906. Similar to composite mirror 806, composite mirror 906 comprises a refractive material 902 and ohmic electrodes 904. The refractive material can comprise a low index of refraction material or a negative index of refraction metamaterial as discussed above. An additional reflective backing layer 908 is interposed between the composite mirror 906 and the conductive metal layer 302. The reflective backing layer 908 provides additional reflectivity for light that passes through composite mirror 806. Reflective backing layer 908 may comprise aluminum, silver, or other reflective materials. Modified surface 910 is shown as a surface of the p-type layer 206; however, other surfaces within device 900 may be modified, or the device 900 may have no modified surfaces.

Although the present invention has been described in detail with reference to certain preferred configurations thereof, other versions are possible. Therefore, the spirit and scope of the invention should not be limited to the versions described above.

We claim:

1. A semiconductor device, comprising:
a carrier wafer having first and second surfaces;
a layer of p-type semiconductor material;
a layer of n-type semiconductor material;
an active region interposed between said layer of p-type material and said layer of n-type material;
a reflective element disposed on a surface of said layer of n-type material opposite from said active region, said reflective element disposed on said first surface of said carrier wafer opposite said layer of n-type material, such that said reflective element is interposed between said n-type material and said carrier wafer.

2. The semiconductor device of claim 1, further comprising:
a p-contact electrode disposed on said p-type layer opposite said active layer; and
a carrier electrode disposed on said second surface of said carrier wafer opposite said reflective element.

3. The semiconductor device of claim 2, further comprising:
a wire bond pad disposed on said p-contact electrode.

4. The semiconductor device of claim 2, wherein said p-contact electrode is textured.

5. The semiconductor device of claim 2, wherein at least one of said n-type layer, said p-type layer and said p-contact electrode is textured.

6. The semiconductor device of claim 2, wherein said p-contact electrode comprises a material selected from the group of zinc oxide, indium tin oxide and platinum.

7. The semiconductor device of claim 1, wherein said reflective element comprises an aluminum mirror.

8. The semiconductor device of claim 1, wherein said reflective element comprises an omnidirectional reflector.

9. The semiconductor device of claim 1, wherein said reflective element comprises a composite mirror having an omnidirectional reflector and at least one ohmic electrode providing an electrical connection between said carrier wafer and said layer of n-type semiconductor material.

10. The semiconductor device of claim 1, wherein said reflective element comprises:
a refractive material having a lower index of refraction than said carrier wafer and said n-type semiconductor material; and
at least one ohmic electrode providing an electrical connection between said carrier wafer and said layer of n-type semiconductor material.

11. The semiconductor device of claim 10, wherein said reflective element further comprises a reflective backing layer interposed between said refractive material and said carrier wafer.

12. The semiconductor device of claim 1, wherein said n-type layer is textured.

13. The semiconductor device of claim 1, wherein said p-type layer is textured.

14. The semiconductor device of claim 1, wherein said carrier wafer comprises silicon.

15. The semiconductor device of claim 1, wherein said carrier wafer is bonded to said reflective element using a eutectic metal bond.

16. The semiconductor device of claim 1, wherein said semiconductor device is a light emitting diode (LED).

17. The semiconductor device of claim 1, wherein said carrier wafer comprises a conductive material.

18. The semiconductor device of claim 1, wherein said semiconductor materials are nitride-based.

19. A semiconductor device, comprising:
a light emission region having an active layer interposed between a layer of p-type semiconductor material and a layer of n-type semiconductor material;
a reflective element disposed on said n-type semiconductor layer opposite said active layer; and
a conductive metal layer disposed on said reflective element opposite said layer of n-type semiconductor material, said conductive metal layer structured to provide mechanical support for said semiconductor device.

20. The semiconductor device of claim 19, further comprising:
a p-contact electrode disposed on said layer of p-type semiconductor material opposite said active layer.

21. The semiconductor device of claim 20, wherein said p-contact electrode is textured.

22. The semiconductor device of claim 20, wherein at least one of said n-type layer, said p-type layer and said p-contact electrode is textured.

23. The semiconductor device of claim 20, wherein said p-contact electrode comprises a material selected from the group of zinc oxide, indium tin oxide and platinum.

24. The semiconductor device of claim 20, further comprising:
a wire bond pad disposed on said p-contact electrode.

25. The semiconductor device of claim 19, wherein said reflective element comprises an aluminum mirror.

26. The semiconductor device of claim 19, wherein said reflective element comprises an omnidirectional reflector (ODR).

27. The semiconductor device of claim 19, wherein said reflective element comprises a composite mirror having an ODR and at least one ohmic electrode providing an electrical connection between said conductive metal layer and said layer of n-type semiconductor material.

28. The semiconductor of device of claim 19, wherein said reflective element comprises:
a refractive material having a lower index of refraction than said conductive metal layer and said n-type semiconductor material; and
at least one ohmic electrode providing an electrical connection between said conductive metal layer and said layer of n-type semiconductor material.

29. The semiconductor device of claim 28, said reflective element further comprising a reflective backing layer interposed between said refractive material and said conductive metal layer.

30. The semiconductor device of claim 19, wherein said n-type layer is textured.

31. The semiconductor device of claim 19, wherein said p-type layer is textured.

32. The semiconductor device of claim 19, wherein said semiconductor device is a light emitting diode (LED).

33. The semiconductor device of claim 19, wherein said semiconductor materials are nitride-based.

34. A method for fabricating semiconductor devices, comprising:
providing a substrate suitable for growing epitaxial semiconductor layers;
growing at least one n-type semiconductor layer on said substrate;
growing an active region on said at least one n-type layer;
growing at least one p-type semiconductor layer on said active region;
forming a p-contact electrode on said at least one p-type layer;
flipping said semiconductor device a first time and mounting said semiconductor device to a sacrificial carrier such that said n- and p-type layers are interposed between said substrate and said sacrificial carrier;
removing said substrate such that a portion of said at least one n-type layer is exposed;
forming a reflective element on said at least one n-type layer;
flipping said semiconductor device a second time and mounting said reflective element on a support element; and
removing said sacrificial carrier.

35. The method of claim 34, wherein said support element comprises a carrier wafer.

36. The method of claim 35, wherein said carrier wafer comprises silicon.

37. The method of claim 35, wherein said carrier wafer comprises a conductive material.

38. The method of claim 34, wherein said reflective element is bonded to said carrier wafer using a eutectic metal bond.

39. The method of claim 34, wherein said support element comprises a conductive metal layer.

40. The method of claim 39, wherein said conductive metal layer is applied to said reflective element by electroplating.

41. The method of claim 34, further comprising texturing said at least one n-type semiconductor layer.

42. The method of claim 34, further comprising texturing said at least one p-type semiconductor layer.

43. The method of claim 34, further comprising texturing said p-contact electrode.

44. The method of claim 34, further comprising forming a wire bond pad on said at least one p-type semiconductor layer.

45. The method of claim 34, wherein said semiconductor device is mounted to said sacrificial carrier with a removable polymer adhesive.

46. The method of claim 34, wherein said reflective element comprises an aluminum mirror.

47. The method of claim 34, wherein said reflective element comprises an omnidirectional reflector (ODR).

48. The method of claim 34, wherein said reflective element comprises a composite mirror having an ODR and at least one ohmic contact providing an electrical connection between said at least one layer of n-type semiconductor material and said support element.

49. The method of claim 34, wherein said p-contact electrode comprises a material selected from the group of zinc oxide, indium tin oxide, gold and platinum.

50. The method of claim 34, wherein said semiconductor device is a light emitting diode.

51. The method of claim 34, wherein said p-contact electrode is formed after removing said sacrificial layer.

52. A semiconductor device, comprising:
a layer of p-type semiconductor material;
a layer of n-type semiconductor material;
an active region interposed between said layer of p-type material and said layer of n-type material;
a reflective element disposed on a surface of said layer of n-type material opposite from said active region;
a support element disposed on said reflective element opposite said layer of n-type material, such that said reflective element is interposed between said layer of n-type material and said support element, said support element structured to provide mechanical support to said semiconductor device.

53. The semiconductor device of claim 52, wherein said reflective element comprises a metamaterial having a negative index of refraction.

54. The semiconductor device of claim 52, further comprising a reflective backing layer interposed between said reflective element and said support element.

55. A semiconductor device, comprising:
a support element;
a layer of p-type semiconductor material;
a processed layer of n-type semiconductor material mounted on said support element; and
an active region interposed between said layer of p-type material and said processed layer of n-type material.

56. The semiconductor device of claim 55, wherein said processed n-type layer comprises a modified surface.

57. The semiconductor device of claim 56, wherein said modified surface is textured.

58. The semiconductor device of claim 56, wherein said modified surface comprises light extraction structures.

59. The semiconductor device of claim 55, further comprising a reflective element that is disposed on said processed n-type layer.

60. The semiconductor device of claim 59, wherein said reflective element comprises a distributed Bragg reflector (DBR).

61. The semiconductor device of claim 59, wherein said reflective element comprises a metal mirror.

62. A double flip-chip semiconductor device, comprising:
a support element;
a first semiconductor layer which was grown on a growth substrate;
a second semiconductor layer grown on said first semiconductor layer;
an active layer interposed between said first and second semiconductor layers;
wherein said first semiconductor layer has been removed from said growth substrate and bonded to said support element.

63. The double flip-chip semiconductor device of claim 62 wherein said first semiconductor layer comprises an n-type material and said second semiconductor layer comprises a p-type material.

64. The double flip-chip semiconductor device of claim 62 wherein said first semiconductor layer comprises a p-type material and said second semiconductor layer comprises an n-type material.

65. The double flip-chip semiconductor device of claim 62 wherein said first semiconductor layer has been processed.

66. The double flip-chip semiconductor device of claim 65 wherein said first semiconductor layer has been processed to have a modified surface.

67. The double flip-chip semiconductor device of claim 62, further comprising a reflective element disposed on said first semiconductor layer between said first semiconductor layer and said support element.

68. The double flip-chip semiconductor device of claim 62 wherein said support element comprises a semiconductor wafer.

69. The double flip-chip semiconductor device of claim 62 wherein said support element comprises a thick layer of metal.
